(19) United States
(12) Patent Application Publication
(10) Pub. No.: US 2025/0202197 A1
(43) Pub. Date: Jun. 19, 2025

(54) LIGHT SOURCE COMPRISING A RESONANT CAVITY WITH DISTRIBUTED FEEDBACK AND METHOD FOR MANUFACTURING A SUCH LIGHT SOURCE

(71) Applicant: COMMISSARIAT A L'ENERGIE ATOMIQUE ET AUX ENERGIES ALTERNATIVES, PARIS (FR)

(72) Inventors: Badhise BEN BAKIR, GRENOBLE CEDEX 09 (FR); Marion VOLPERT, GRENOBLE CEDEX 09 (FR); Toufiq BRIA, GRENOBLE CEDEX 09 (FR)

(21) Appl. No.: 18/978,980

(22) Filed: Dec. 12, 2024

(30) Foreign Application Priority Data
Dec. 14, 2023 (FR) FR2314205

(51) Int. Cl. H01S 5/12; H01S 5/20

(52) U.S. Cl. CPC H01S 5/1237; H01S 5/2018; H01S 5/2081

(57) ABSTRACT

One aspect of the invention relates to a distributed feedback light source (101) comprising a stack of layers (103) extending in parallel to a substrate (102), the source (101) also comprising a first metal layer (111) extending between the substrate (102) and the stack (103).

### TECHNICAL FIELD OF THE INVENTION

The technical field of the invention is that of the integration of a light source, for example of the laser type, comprising a Distributed FeedBack (DFB) resonant cavity.

### TECHNOLOGICAL BACKGROUND OF THE INVENTION

Light sources that can be integrated onto substrates, such as distributed feedback sources, have multiple applications, as for example photoacoustic detection of chemical compounds. In order to take advantage of benefits provided by several distinct technologies, it is sought to integrate light sources manufactured by means of a particular technology onto a substrate not derived from this technology. This is referred to as “hybrid” integration or “hybrid” sources. For example, the integration of light sources made from so-called “III-V” materials onto a silicon semiconductor substrate can be mentioned.

III-V materials are semiconducting alloys comprising a semiconductor material belonging to group III (column 13 of the periodic table of the elements) and a semiconductor material belonging to group V (column 15 of the periodic table of the elements). Common III-V alloys comprise, for example, InP, InAs, GaAs, GaN, InSb or alloys thereof. The so-called “III-V” light sources are good candidates for emitting radiation in a wide spectral range, such as the mid and far infrared. However, these sources have major integration restrictions, especially when they have to be integrated into the silicon substrate.

A distributed feedback light source, whether of III-V type or not, comprises a cavity formed by a stack of layers comprising a so-called “active” or “amplifying” region and two so-called “cladding” semiconducting layers. The active region is configured to emit an electromagnetic field by spontaneous and/or stimulated emission. The cladding layers are adjacent to the active region and disposed on either side thereof to confine some modes of the electromagnetic field, referred to as “guided modes”. A diffraction grating is used to apply feedback to the magnetic field to establish the guided modes. In order to effectively confine the guided mode(s), the cladding layers have optical indices that are strictly lower than the mean optical index of the active region. For example, when the active region is comprised of a multilayer of InGaAs/AlInAs or InAlAs/AlGaInAs, the cladding layers are made of InP.

A III-V light source, whose stack of layers is disposed directly on a Si substrate, can suffer significant optical losses, which hamper its use. Indeed, silicon has a higher optical index than III-V materials such as InP, and therefore higher than the cladding layers in the stack. Thus, without any particular provision and when the penetration of the guided mode into the cladding layers is significant (for example in the mid and far infrared), said guided mode can couple to the Si substrate and reduce the effectiveness of the confinement provided by the cladding layers.

To overcome this problem, it is suggested that the cladding layer separating the active region from the Si substrate, referred to as the lower cladding layer, is relatively thick. This thus compensates for the depth of penetration of the guided mode into the cladding layers and reduces the coupling of the guided mode to the Si substrate. For a guided mode having a wavelength of 4.5 μm, the thickness of the lower cladding layer has to be at least 3.5 μm. This represents an additional restriction to source integration and also a substantial raw material cost. For a guided mode having a wavelength greater than 10 μm (far infrared), the thickness of the lower cladding layer should be greater than 8 μm, which makes the integration of III-V light sources on silicon even more complex.

One solution provided by document [Coutard, J. G., Brun, M., Fournier, M. et al. “Volume Fabrication of Quantum Cascade Lasers on 200 mm-CMOS pilot line”. Sci Rep 10, 6185 (2020)] consists in inserting a layer of low optical index between the lower cladding layer of the stack of layers and the Si substrate. Said low-index layer acts as a barrier to the propagation of the guided mode in the Si substrate and makes it possible to reduce the thickness of the lower cladding layer. Said low-index layer is for example of oxide or nitride. While decoupling between the III-V source and the Si substrate is effective for a guided mode having a wavelength of less than 4 μm, the situation is different when the guided mode has a longer wavelength. Indeed, oxides or nitrides induce high losses when the wavelength of the guided mode is greater than 4 μm, which greatly limits the spectral range of the source.

There is therefore a need to reduce the overall size of a distributed feedback light source, integrated onto a substrate having a high optical index, whatever the spectral range under consideration.

### SUMMARY OF THE INVENTION

The invention makes it possible to solve, at least in part, the aforementioned problems.

More particularly, the invention relates to a light source comprising:
a substrate extending in parallel to a plane;
a Distributed FeedBack (or “DFB”) resonant cavity, configured so that at least one stationary mode of an electromagnetic field, referred to as a “resonant guided mode”, is established in parallel to the substrate, said resonant cavity comprising a stack of:
   a first confinement layer, referred to as the “lower confinement layer”, extending in parallel to the substrate;
   an active layer configured to generate said electromagnetic field, said active layer extending over the lower confinement layer;
   a second confinement layer, referred to as the “upper confinement layer”, extending over the active layer.

The light source is remarkable in that the resonant cavity comprises a metal layer, referred to as the “lower metal layer”, extending in parallel to the substrate, between the substrate and the stack of layers and in that the lower confinement layer extends against the lower metal layer.

By “parallel” or “in parallel” to a plane or direction and respectively “perpendicular” or “perpendicularly” to a plane or direction, it is meant parallel to the plane or direction to within 20° (that is, at an angle to the plane or direction within [−20°; +20°]) or even within 10°, and respectively perpendicular to the plane or direction to within 20° (that is, at an angle to the plane or direction within [70°; 110°]) or even within 10°.

The lower metal layer replaces the oxide or nitride layer described in document [Coutard, J. G., Brun, M., Fournier, M. et al. “Volume Fabrication of Quantum Cascade Lasers on a 200 mm-CMOS pilot line”. Sci Rep 10, 6185 (2020)] discussed above. The lower metal layer does not have the absorption problems of oxide or nitride layers.

The presence of the lower metal layer prohibits transmission of resonant guided modes to the substrate. It thus improves confinement of the resonant guided modes in the stack. Thus, even if the substrate has a higher optical index than the effective index seen by the resonant guided modes in the cavity, the lower metal layer prohibits transmission of the modes to the substrate. The lower metal layer therefore enables the source to be integrated onto a substrate with a high optical index, for example of silicon.

Propagation of the resonant guided mode in the substrate, that is, outside the cavity, induces high optical losses. The lower metal layer, by its metallic nature, can also induce optical losses, especially by absorbing part of the radiation. However, the optical losses due to the lower metal layer are lower than the optical losses in the substrate. The lower confinement layer can therefore be thinner relative to a source of prior art with a relatively thick confinement layer. The source according to the invention can therefore be integrated onto a substrate having a high index while having a reduced overall size.

The interaction of the resonant guided mode with the lower metal layer takes place over a wide spectral range. More precisely, the refractive indices of metals, such as gold, exhibit a very high imaginary part (for example greater than 10 for gold), increasing significantly with wavelength. This has the effect of very drastically limiting the penetration of the optical mode into the metal layer. The penetration length of an infrared mode into gold is less than 100 nm, for example. Consequently, any propagation in the substrate is prohibited. Thus the thickness of the lower metal layer varies little, if at all, over a wide spectral range of resonant guided modes. The thickness of the lower metal layer can therefore be constant over a wide spectral range. The vertical overall size of the source (that is, measured perpendicularly to the substrate) varies little, if at all, over a wide spectral range.

It was not obvious to the person skilled in the art how to replace the oxide layer described in document [Coutard, J. G., Brun, M., Fournier, M. et al. “Volume Fabrication of Quantum Cascade Lasers on 200 mm-CMOS pilot line”. Sci Rep 10, 6185 (2020)] by the lower metal layer and deposit the first lower confinement layer against this lower metal layer. Indeed, due to the wave-like nature of the resonant guided modes in a DFB cavity, all the constituent elements of the source are intertwined. Confinement therefore results from multiple correlations between the constituent elements of the source. This is demonstrated by the fact that infrared optical source dimensioning generally involves a numerical calculation step, which is the only way of determining the effect of modifying one of the constituent elements of the source. Perturbative reasoning (that is, considering the constituent elements of the source as being decorrelated from one another) does not allow the effect of modifying one of the elements on the resonant guided modes to be determined. Indeed, the mere use of the general knowledge of the person skilled in the art would not have enabled them to anticipate the effect of switching the oxide layer of the aforementioned document by a metal layer. They would not, for example, have expected the lower metal layer to improve the overall size of the source while reducing the optical losses of the resonant guided modes.

The lower metal layer can also be used as an electrical contact (in other words as an electrode) to carry out charge carrier injection into the stack in order to stimulate generation of resonant guided modes.

The lower metal layer also enables the heat generated by the stack to be dissipated more efficiently to outside. Indeed, metals are good thermal conductors. The lower metal layer in contact with the stack makes it possible to carry out conduction thermal transfer from the stack to a cold point (such as the substrate or a heat sink). The efficiency of a light source is highly dependent on its temperature. The lower metal layer therefore improves the efficiency of the source.

By optical index, it is also meant refractive index. By effective optical index, it is meant the optical index seen by the resonant guided mode in the stack.

Advantageously, the stack of layers has a height, measured perpendicularly to the substrate, the stack of layers further comprising a first side, extending perpendicularly to the substrate over at least part of the height of the stack of layers and extending in parallel to a first direction parallel to the substrate referred to as the “direction of propagation”, the stack of layers having, on its first side, a first diffraction grating configured to apply distributed feedback to said at least one resonant guided mode.

The first diffraction grating makes it possible to carry out distributed feedback on the resonant guided modes and thus select at least one resonant guided mode in the resonant cavity.

Forming the diffraction grating on one side of the stack instead of making it on the stack further reduces the total thickness of the source. Indeed, positioning a diffraction grating on or under the stack of layers means depositing a sufficient thickness of material to etch the diffraction grating. According to the etching depth of the grating or the optical indices of the materials making up the grating, this thickness could prove significant.

Advantageously, the first side extends over a height of the upper confinement layer, over a height of the active layer and at least over part of a height of the lower confinement layer. The first side can also extend over the entire height of the lower confinement layer.

Advantageously, the stack of layers has a width, measured perpendicularly to the direction of propagation, the first diffraction grating being formed so that the width of the stack of layers varies periodically as a function of a position along the direction of propagation.

The diffraction grating therefore has a series of slits or trenches extending perpendicularly to the substrate and forming, along the direction of propagation, a diffraction grating. When the diffraction grating is positioned on one side, each slit or trench can be dug as deep as desired (towards the centre of the stack). It is therefore possible to adjust coupling of the diffraction grating to the resonant guided modes without increasing the height of the source. Slits extending perpendicularly to the substrate are also easier to etch.

Forming lateral diffraction gratings also makes it possible to manufacture several different sources on a same substrate and/or during a same manufacturing step. The sources can especially have gratings with different coupling forces. Forming lateral diffraction gratings makes it possible to etch corrugations (or structurations) of different depths in a same step (the depth of a corrugation for a lateral grating being measured in parallel to the substrate). Conversely, forming a grating on or under the stack (for example as carried out in the above-mentioned document [Coutard 2020]) requires gratings to be formed with the same corrugation depths (the depth being measured perpendicularly to the substrate) and therefore the same coupling forces for all the sources.

Advantageously, the first diffraction grating has a first length, measured along the direction of propagation, and, for at least one resonant guided mode of the resonant cavity, a first coupling force with said resonant guided mode, the product of the first coupling force for said at least one resonant guided mode with the first length of the diffraction grating being between 1 and 2.5.

The coupling force can be seen as a constant proportional to a contrast of effective indices seen by the resonant guided modes interacting with the diffraction grating. The contrast is usually defined as a difference in the effective indices Δn of said resonant guided mode in etched and unetched zones of the grating. The coupling force κ is calculated by, for example

$$κ = \frac{2 Δ n}{λ}$$

where λ is the wavelength of the resonant guided mode under consideration. The different effective indices seen by the resonant guided modes depend on the shape of the etched and unetched zones, the depth of the etched zones relative to the unetched zones, as well as their duty factor.

Retaining a product of the length with the coupling force of between 1 and 2.5 results in an efficient resonant cavity. The first grating thus has sufficient force to apply distributed feedback to the electromagnetic fields in the stack.

Advantageously, the stack of layers comprises a second side, opposite to the first side, and extending over at least part of the height of the stack of layers, the stack of layers having, on its second side, a second diffraction grating configured to apply distributed feedback to said at least one resonant guided mode, the first diffraction grating having a first pitch and the second diffraction grating having a second pitch equal to the first pitch.

By “the second pitch equal to the first pitch”, it is meant that the second pitch is equal to the first pitch to within 20%, or even within 10%.

The second grating thus enhances the distributed feedback in the resonant cavity. It also provides the same advantages in terms of overall size and ease of manufacture as the first diffraction grating.

Preferentially, the second side extends over the height of the upper confinement layer, the height of the active layer and at least over part of the height of the lower confinement layer. The second side can also extend over the entire height of the lower confinement layer.

Advantageously, the second diffraction grating has a second length and a second coupling force with said at least one resonant guided mode, the product of the second coupling force with the second length also being between 1 and 2.5.

Advantageously, the stack of layers has a first face, referred to as the “lower face”, and a second face, referred to as the “upper face”, opposite to the lower face, the lower metal layer extending against the lower face of the stack of layers.

Advantageously, the stack of layers has, on its upper face, a third diffraction grating configured to apply distributed feedback to said at least one resonant guided mode. The third diffraction grating makes it possible to further enhance the distributed feedback.

Advantageously, the third diffraction grating has a third pitch equal to the first pitch. Thus feedback is enhanced.

Advantageously, the lower confinement layer has a first thickness, measured perpendicularly to the substrate, for which optical losses of at least one resonant guided mode of the stack are a function of the first thickness in an asymptotic state.

Part of the resonant guided mode in the cavity can be absorbed by the lower metal layer due to the metallic nature of the latter. Increasing the first thickness of the lower confinement layer reduces the level of absorption in the metal layer. The course trend of optical losses as a function of the first thickness can be used to determine a thickness corresponding to acceptable optical losses. One criterion for selecting the first thickness is, for example, the asymptotic state of the optical losses. In the asymptotic state, the first thickness increases faster than the losses are reduced. In this state, the first one is thus sufficiently thick.

Advantageously, the resonant cavity also comprises an additional metal layer, referred to as the “upper metal layer”, extending against the upper face of the stack, the second upper confinement layer present having a second thickness, measured perpendicularly to the substrate, for which optical losses of at least one resonant guided mode of the stack are a function of the second thickness in an asymptotic state.

The upper metal layer provides several advantages. For example, it makes it possible to carry out, with the lower metal layer, injection of charge carriers to stimulate photon emission from the stack (in this case from an active layer). Thus, it is not necessary to use conductive and transparent interstitial layers (with the selected guided modes) inserted into the stack to carry out a transfer of electrical contacts. Stack manufacture is simplified and carrier injection is standardised.

The presence of the upper metal layer can also block the transmission of guided modes outside the cavity, in the same way as the lower metal layer (and in the presence of a medium with a high optical index). It does, however, have the disadvantage of inducing losses due to its metallic nature. However, by selecting a second thickness of the upper confinement layer as a function of the course state of the losses as a function of the second thickness, it is possible to obtain a source with acceptable losses and a reasonable thickness.

Advantageously, the lower metal layer is made from Au, Ag or Ti.

The invention also relates to a method for manufacturing a light source comprising the steps of:
providing a first substrate having a first face;
providing a second substrate having a second face;
metallising the first face of the first substrate so as to form a first metal sublayer extending over the first face of the first substrate;
metallising the second face of the second substrate so as to form a second metal sublayer extending over the second face of the second substrate;
transferring the second metal sublayer of the second substrate onto the first metal sublayer of the first substrate so that the first and second metal sublayers form a metal layer, referred to as the “lower metal layer”, extending in parallel to the first substrate;
forming a distributed feedback resonant cavity configured so that at least one stationary mode of an electromagnetic field, referred to as a “resonant guided mode”, is established in parallel to the first substrate, forming the resonant cavity comprising the steps of:
   etching the second substrate so as to form a first confinement layer, referred to as the “lower confinement layer”, extending in parallel to the first substrate and against the lower metal layer;
   forming an active layer, configured to generate said electromagnetic field, said active layer extending over the lower confinement layer; and
   forming a second confinement layer, referred to as the “upper confinement layer”, extending over the active layer.

This method makes it possible to manufacture a light source according to the invention which can take advantage of a metal-to-metal transfer of two substrates made of different materials, for example Si and III-V material.

Advantageously, the method comprises a step of determining a first thickness for the lower confinement layer, for which optical losses of at least one resonant guided mode of the resonant cavity are a function of this first thickness in an asymptotic state, the step of etching the second substrate being carried out so that the resulting lower confinement layer has the first thickness determined.

Advantageously, the method comprises a step of determining a second thickness for the upper confinement layer, for which optical losses of at least one resonant guided mode of the resonant cavity are a function of this second thickness in an asymptotic state, the step of forming the upper confinement layer being carried out so that the resulting upper confinement layer has the second thickness determined.

Advantageously, the step of determining the second thickness is carried out before the step of determining the first thickness. This makes it possible to achieve optimisation of the first thickness by considering a second thickness that is already optimal. Determining the first thickness is therefore not disturbed by a second, non-optimised thickness.

Advantageously, the method comprises etching the stack of layers so that said stack of layers, having a height measured perpendicularly to the first substrate, comprises a first side, extending perpendicularly to the first substrate over at least part of the height of the stack of layers and extending in parallel to a first direction parallel to the first substrate, referred to as the “direction of propagation”, etching the stack of layers being carried out so that the stack of layers has, on its first side, a first diffraction grating configured to apply distributed feedback to said at least one resonant guided mode.

Advantageously, the method comprises a step of conformally depositing a first insulating layer against the first side of the stack of layers and a step of conformally depositing an additional metal layer onto the first insulating layer.

### BRIEF DESCRIPTION OF THE FIGURES

The invention and its different applications will be better understood upon reading the following description and upon examining the accompanying figures. The figures are set forth by way of indicating and in no way limiting purposes of the invention. Unless otherwise specified, a same element appearing in different figures has a single reference.

FIG. 1 and FIG. 2 show a first embodiment of a light source according to the invention.

FIG. 3 shows a first result of a modal analysis made from a light source according to the invention.

FIGS. 4 and FIG. 5 show the second and third results of a modal analysis made from a light source according to the invention.

FIG. 6 shows a step in a manufacturing method according to the invention, enabling the light source of FIGS. 1 and 2 to be manufactured.

### DETAILED DESCRIPTION

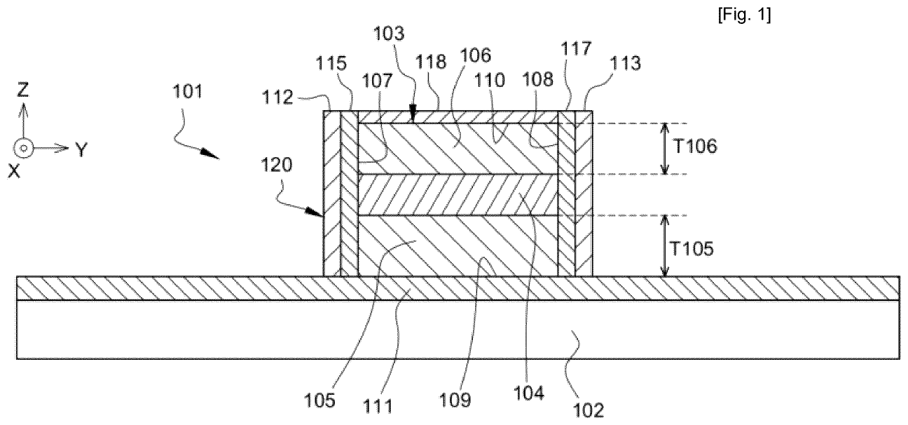

FIGS. 1 and 2 schematically represent a first embodiment of a light source 101 according to the invention. They further show an orthonormal reference frame {X; Y; Z}. FIG. 1 represents a cross-section view in a plane {Y; Z}, while FIG. 2 represents a cross-section view in a plane {X; Y}.

The light source 101 comprises a substrate 102 and a resonant cavity 120.

The substrate 102 extends in parallel to a plane {X; Y}. FIG. 1 represents only a portion of the substrate 102. As the latter can be a bulk substrate, it can have very large dimensions relative to the other elements of the source 101. The substrate 102 is of silicon, for example.

The resonant cavity 120 is, for example, a laser source cavity or an electroluminescent source cavity. The cavity 120 is advantageously configured to carry out emission of a light beam in a range of wavelengths of between 0.8 μm and 20 μm, comprising the near infrared and part of the mid infrared. The cavity 120 is referred to as a “front emission” cavity. This means that the emission is carried out by a lateral surface of the cavity 120, oriented in this case along a first direction X, also called the “direction of propagation”.

In the embodiment of FIG. 1, the cavity 120 has a ridge shape, stretching out along the direction of propagation X. In other words, it has a large aspect ratio with a length, measured along X, of between 20 μm and 1000 μm, or even between 100 μm and 5000 μm, and a width, measured along a second direction Y, parallel to the direction of propagation X, of between 5 μm and 100 μm, and preferentially between 5 μm and 20 μm. The cavity 120 may have a height, measured along a third direction Z, of between 2 μm and 20 μm, and preferentially between 2 μm and 10 μm.

The cavity 120 is configured to emit an electromagnetic field and to confine this electromagnetic field in one or more stationary modes also called “resonant guided modes” (or called “guided modes” or “resonant modes”). These may be guided modes, such as those observable in a laser source. The cavity is particular in that each guided mode is parallel to the plane {X; Y} (that is, parallel to the substrate 102). By mode parallel to the plane, it is meant that the field has, exclusively:
polarisation of the electric field perpendicular to the plane {X; Y}; or
polarisation of the magnetic field perpendicular to the plane {X; Y}.

In other words, the electromagnetic field comprises, for example:
polarisation of the electric field normal to the substrate 102 (that is, parallel to the direction Z) and polarisation of the magnetic field parallel to the substrate 102; or
polarisation of the electric field bias parallel to the substrate 102 and polarisation of the magnetic field normal to the substrate 102.

The cavity 120 implements distributed feedback to enable resonant modes to be established. In this case, it comprises two lateral diffraction gratings 201, 202 (discussed below) to carry out the distributed feedback on the electromagnetic field.

Unless otherwise stated, only one guided mode of the field in the cavity 120 will be considered, in order to simplify description of the invention. The teachings apply, however, to each guided mode when the cavity 120 is configured to have a plurality of modes.

In the embodiment of FIG. 1, the cavity 120 comprises a stack 103 of layers, each layer extending in parallel to the substrate 102. The stack 103 comprises, for example, an active layer 104, also called an “active region” or “amplifying region”. The active layer 104 is configured to emit the electromagnetic field. The stack 103 also comprises a first confinement layer 105, referred to as the “lower confinement layer” or “lower cladding layer”, extending between the active region 104 and the substrate 102. The active layer 104 rests on the lower confinement layer 105. The stack 103 also comprises a second confinement layer 106, referred to as the “upper confinement layer” or “upper cladding layers”, resting on the active region 104. The terms “lower” and “upper” are considered in relation to the orientation of FIG. 1. The active layer 110 separates the two confinement layers 105, 106. The three layers 104, 105, 106 thus form a vertical stack of layers, each layer 104, 105, 106 extending in parallel to the substrate 102. Said stack 103 is delimited by a flank extending perpendicularly to the substrate 102. Said flank especially comprises two surfaces 107, 108 forming a first side 107 and a second side 108. The two sides 107, 108 are opposite to each other. The first side 107 is oriented along-Y and the second side 108 is oriented along +Y.

The confinement layers 105, 106 contribute to the confinement of the electromagnetic field in the cavity 120, especially along the direction Z, normal to the substrate 102. In this way, the electromagnetic field remains mainly located at the active layer 104 and, for example, makes it possible to promote stimulated emission from the active layer 104. For this, the confinement layers 105, 106 are for example configured to have optical indices n₁₀₅, n₁₀₆ strictly lower than a mean optical index n₁₀₄ of the active layer 104. By mean optical index n₁₀₄ of the active layer 104, it is meant an optical index taking account of the indices of the layers or sublayers making up the active layer 104.

The confinement layers 105, 106 are for example made of a III-V alloy such as InP.

The active layer 104 can be configured so that the emission of the electromagnetic field is at least spontaneous and preferentially spontaneous and stimulated. The latter case allows a laser mode operation of the source 101. The emission can be based on inter-band emission, also called “interband cascade emission”. Preferentially, it may be based on inter-band emission, also called as quantum cascade emission. To enable quantum cascade emission, the active layer 104 comprises, for example, a stack of sublayers of III-V material, forming a succession of quantum wells and potential barriers. The stack of sublayers extends in parallel to the substrate, for example. The active layer 104 comprises, for example, a multilayer of InGaAs/AlInAs or InAlAs/AlGaInAs.

The different layers 104, 105, 106 of the cavity 120 have different optical indices. However, each guided mode in the cavity 120 may have an effective optical index n_{eff} which may have a different value to the optical indices of the layers of the stack 103 considered independently of each other. This difference is especially due to the geometry of the different layers. This is the reason why the effective optical index n_{eff} of the guided mode is considered. The effective optical index n_{eff} can be determined numerically. An estimate of the effective optical index n_{eff} can be determined from the mean optical index in the stack 103. It is however preferable to take account of all the elements making it possible to carry out the confinement of the electric field in the cavity 120, such as the geometry (thickness and/or width) of the stack 103 and/or the presence of reflective layers.

The substrate 102 has an optical index n₁₀₂. When n_{eff}>n₁₀₂, the guided mode of the cavity 120 is not likely to couple with the substrate 102. The substrate 102 takes part in the confinement of the guided modes in the cavity 120. On the other hand, when n_{eff}<n₁₀₂, the guided mode in the cavity 120 is likely to couple with the substrate 102, inducing optical losses and reducing the efficiency of the source 101.

The source 101 comprises the insertion of a first metal layer 111, referred to as the “lower metal layer”, between the substrate 102 and the stack of layers 103. The lower metal layer 111 extends in parallel to the substrate 102 and the first confinement layer 105 extends against this lower metal layer 111. The lower metal layer 111 may extend away from or against the substrate 102. The interaction of the guided modes in the cavity 120 with the surface of the lower metal layer 111 maintains the guided modes in the cavity 120. In this way, transmission of the guided modes to the substrate 102 is inhibited and the efficiency of the source 1 is retained, even though the substrate 102 would have a high optical index allowing it to couple with the guided modes in the cavity 120.

In the embodiment of FIG. 1, the lower metal layer 111 extends against the substrate 102. The stack 103 rests, by its first confinement layer 105, against the lower metal layer 111. The lower metal layer 111 extends over the substrate 102, under the stack 103 and beyond the stack 103. The lower metal layer may be made of gold, silver or titanium. It has a thickness, measured perpendicularly to the substrate 102, greater than or equal to λ/10 where λ is the wavelength of the guided mode under consideration. Considering a range of wavelengths λ of between 0.8 μm and 20 μm, the thickness of the lower metal layer 111 is, for example, between 80 nm and 2 μm.

The cavity 120 also comprises a first insulating layer 115 and a second insulating layer 117 extending against, respectively, the first and second sides 107, 108 of the stack 103. The insulating layers preferentially have optical indices lower than the effective optical index in the cavity. Thus these layers make a confinement by index contrast. These insulating layers 115, 117 are made, for example, of silicon nitride SiN.

The cavity 120 also comprises a second metal layer 112 and a third metal layer 113. In the embodiment of FIG. 1, the second and third metal layers 112, 113 extend perpendicularly to the substrate 102 and in parallel to, respectively, the first and second sides 107, 108 of the stack 103. The second metal layer 112 extends against the first insulating layer 115, covering the first side 107. The third metal layer 113 extends against the second insulating layer 117, covering the second side 108.

The second and third layers 112, 113 enable the guided modes to be confined laterally or the lateral confinement provided by the index contrast of the insulating layers 145, 117 to be improved.

The first and second insulating layers 115, 117 enable the stack 103 to be electrically insulated from the second and third metal layers 112, 113. Indeed, the injection of charge carriers, making it possible to stimulate the emission of an electromagnetic field, is preferably carried out along a direction perpendicular to the substrate. Thus, the insulating layers 115, 117 make it possible to avoid short-circuiting the active layer 104 and in particular the different sublayers that may make up this active layer 104.

In the embodiment, the second and third metal layers 112, 113 are electrically connected to the lower metal layer 111, with which they are in direct contact. This connection fixes the electrical potential of the second and third metal layers 112, 113.

The stack 103 comprises two faces 109, 110, opposite to each other: a first face 109, referred to as the “lower face”; and a second face 110, referred to as the “upper face”. The lower face 109 of the stack corresponds to the face of the first confinement layer 105 in contact with the lower metal layer 111.

The cavity 120 comprises a fourth metal layer 118, also called the “additional metal layer” or “upper metal layer”, extending against the upper face 110 of the stack 103. Thus, the stack 103 is sandwiched between two metal layers 111, 118 which can act as electrodes. These electrodes enable an electric field to be applied to the stack 103 to assist photon generation in the cavity 120 and more specifically not in the active region 104.

In order to be able to apply a field between the lower and upper metal layers 111, 118, said metal layers 111, 118 are electrically insulated from each other. In the embodiment of FIG. 1, the lateral metal layers 112, 113 are electrically connected to the lower metal layer 111. The upper metal layer 118 is therefore insulated from the lateral metal layers 112, 113. In particular, in the embodiment of FIG. 1, the first and second insulating layers 115, 117 extend vertically, beyond the stack 103 to cover edges of the fourth metal layer 118.

Alternatively, the lateral metal layers 112, 113 could be electrically connected to the upper metal layer 118 and insulated from the lower metal layer 111. Still alternatively, the lateral metal layers 112, 113 could be connected to a different metal layer 111, 118. Still alternatively, the lateral metal layers 112, 113 could be insulated from the upper and lower metal layers 111, 118.

The second, third and fourth metal layers 112, 113, 118 can be made from gold, silver or titanium or from different metal materials.

In order to activate the spontaneous emission of the active layer 104, the confinement layers 105, 106 can be doped, promoting conduction of the electric current through the active layer 104.

The cavity 120 of FIGS. 1 and 2 implements distributed feedback of the resonant modes, referred to as “DFB”. In a DFB cavity, the resonant guided modes are established in response to the action of a diffraction grating extending over one face of said cavity. In the case of the cavity 120 of FIGS. 1 and 2, the stack 103 has lateral corrugations at its first and second sides 107, 108. The shape and period of these corrugations as well as the index contrast (between the stack and the insulating layers 115, 117 in this case) form first and second diffraction gratings 201, 202, referred to as “lateral diffraction gratings”. In this way, the guided modes in the cavity 120 can interact with these lateral diffraction gratings.

In the example of FIG. 2, the lateral diffraction gratings 201, 202 are formed by periodic trenches, extending perpendicularly to the substrate 102 (therefore along the direction Z), dug into the stack 103 along the direction Y. These trenches form a periodic corrugation at the sides of the stack 103. The trenches are distributed along the direction of propagation X. They are arranged, for the first and second lateral gratings 201, 202, according to, respectively, first and second constant pitches P201, P202, measured along the direction of propagation X. In this way, each guided mode is established in parallel to the substrate 102 and mainly in the length of the cavity 120, in other words along the direction of propagation X in FIGS. 1 and 2.

In a top view, the lateral corrugations of FIG. 2 have straight shapes, similar to teeth dug into the stack 103. The shape of the corrugations can be different if they have periodic patterns. They may be waves or triangles. From the point of view of manufacturing these corrugations, however, it may be easier to etch straight teeth into the sides of the stack 103.

In the example of FIG. 2, the insulating layers 115, 117 extend against the sides 107, 108 of the stack 103 and especially conformally against the lateral corrugations. Similarly, the lateral metal layers 112, 113 extend conformally against the insulating layers 115, 117. Since the diffraction gratings 201, 202 are partly formed by virtue of the index contrast with the stack 103, the insulating layers can be deposited differently. For example, in an alternative, the insulating layers 115, 117 can be deposited non-conformally against the lateral corrugations so as to smooth out the corrugations. In this case, the metal layers 112, 113 extend against the insulating layers 115, 117 in a planar manner.

The first and second pitches P201, P202 of the two lateral gratings 201, 202 are preferably equal, for example to within 10% or even 5%. Thus, they constructively reinforce the feedback exerted on the modes in the cavity 120.

The stack 103 can also comprise a third diffraction grating on its upper face 110. It can have, similarly to the first and second lateral gratings 201, 202, a periodic corrugation formed of trenches distributed along the direction of propagation X, with a constant third pitch, preferably equal to the first pitch P201 of the first lateral grating 201. The trenches of the third network extend, however, along a different direction, for example along the direction Y (they can be obtained by partially etching the stack 103 along the direction −Z).

Complementarily, the stack 103 may also comprise an additional diffraction grating on its lower face 109, on the same principle as set forth above.

It is advantageous, however, for the cavity 120 to comprise only the lateral diffraction gratings 201, 202. Indeed, these gratings make it possible to obtain distributed feedback on the guided modes, while retaining a small vertical overall size. Indeed, it is not necessary to dispose a thick layer on (or under) the stack 103 to make an etching enabling a diffraction grating to be obtained. Furthermore, forming a lateral grating is simple to implement. It can be carried out by anisotropic etching of the sides 107, 108 of the stack 103. It is also easy to form lateral gratings with different pitches (and therefore different orders) within a same stack 103 or for different stacks 103 of a same set of stacks 103 (for example manufactured in a same step).

The lateral gratings 201, 202, as illustrated schematically in FIG. 2, have a length L201, L202, measured along the direction Z, equal to 20% of the length of the stack 103. The gratings 201, 202 are made by etching slits in the stack 103.

In the example of FIG. 2, the stack 103 has a width W, measured perpendicularly to the direction of propagation Z, varying between two extreme widths W0 and W1. The difference between these two extreme widths corresponds to the depth D201, D202 of the corrugations (in this case the trenches), measured along the direction Y.

A coupling force κ₂₀₁, κ₂₀₂ can be defined for each lateral grating 201, 202. This coupling force is proportional to the interaction of each guided mode in the stack 103 with the diffraction gratings 201, 202. Each guided mode interacts with a total coupling force κ corresponding to the sum of the coupling forces of the cavity 120.

The coupling forces κ₂₀₁, κ₂₀₂ of the lateral gratings are proportional to the contrasts Δn₂₀₁, Δn₂₀₂ of the effective indices seen by the guided modes for each lateral grating 201, 202. The contrasts Δn₂₀₁, Δn₂₀₂ are a function of the difference in effective indices seen by the guided modes in etched zones of the grating (so, for example, the indices of the insulating layers 115, 117) and non-etched zones of the grating. They also depend on the depth D201, D202 and the duty factors of the trenches forming the diffraction gratings 201, 202. For example, up to a limit, the deeper the trenches, the greater the contrast. Δn₂₀₁, Δn₂₀₂.

The coupling forces κ₂₀₁, κ₂₀₂ of the lateral gratings can be calculated by

$${κ}_{201} = \frac{2 Δ {n}_{201}}{{λ}^{i}} ; {κ}_{202} = \frac{2 Δ {n}_{202}}{{λ}^{i}}$$

where λⁱ is the wavelength of the guided mode i under consideration.

Retaining a product of length L201, L202 with a coupling force κ₂₀₁, κ₂₀₂ so that

$$L 201 \times {κ}_{201} ∈ [ 1 ; 2.5 ]$$

$$L 202 \times {κ}_{202} ∈ [ 1 ; 2.5 ]$$

makes it possible to obtain an efficient source 1, with sufficient total feedback for the establishment of guided modes while limiting the absorption of the modes by the gratings 201, 202.

The lateral gratings 201, 202 have preferentially equal pitches P201, P202, in order to make distributed feedback on the same guided modes. However, the depths D201, D202 or lengths L201, L202 of the gratings 201, 202 do not have to be equal. The lengths of the lateral gratings 201, 202 are however advantageously equal to the length, measured along the direction of propagation X, of the cavity 120. In this way it is not necessary to form deep slits, thus limiting the attenuation of the modes by the gratings 201, 202.

In an alternative embodiment, the lower confinement layer 105 may have a different shape, especially comprising a part, referred to as a “pedestal”, extending laterally beyond the active region 104. The lower confinement layer 105 comprises, for example, first and second sublayers, each extending in parallel to the substrate 102 and one over the other. The first sublayer is in contact with the active region 104. For example, it extends from the active region 104 vertically (that is, perpendicularly to the substrate 102). It can be delimited by a flank, common to the flank delimiting the active region 104.

The second sublayer forms the pedestal. It extends against the lower metal layer 111. The first sublayer extends against the second sublayer. The second sublayer extends under the active region 104 and extends laterally beyond the active region 104. The second sublayer extends, for example, against the entire lower metal layer 111.

In this embodiment, the first side 107 of the stack 103 extends only over some height (measured perpendicularly to the substrate 102) of the stack 103. In particular, it extends over the entire height of the active region 104 and the entire height of the upper confinement layer 106. The first side 107, on the other hand, extends against only part of the height of the lower confinement layer 105, in particular over the entire height of the first sublayer of the lower confinement layer 105. Likewise, in this embodiment, the second side 108 of the stack 103 extends only over the height of the active region 104, the height of the upper confinement layer 106 and the height of the first sublayer of the lower confinement layer 105.

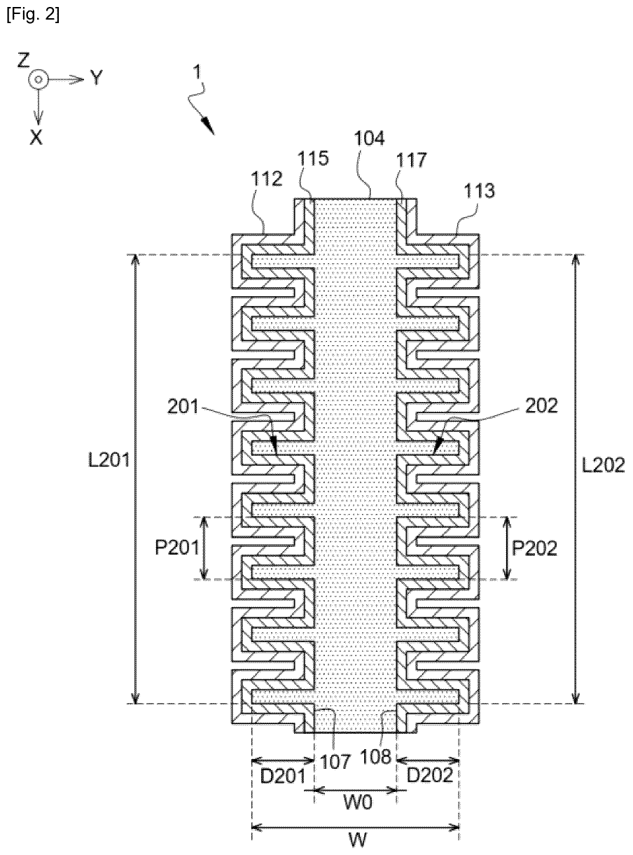

FIG. 3 shows a result of a modal analysis made using finite elements to adjust the depths D201, D202 of the diffraction gratings 201, 202 to obtain a predefined total coupling force κ. FIG. 3 shows more particularly the result of a parametric study of the effective index n_{eff} seen by a guided mode TM00 (polarisation perpendicular to the substrate 102) in a stack 103 according to the invention but without corrugation on its sides (that is, with flat sides), and as a function of the width W of the stack 103 (constant over the entire length of the stack, without a pedestal).

Modal analysis is made by considering a complex effective index n_{eff}, that is comprising a real part and an imaginary part. The imaginary part accounts for the optical losses of the guided mode in the cavity 120.

FIG. 3 shows the course of the real part of the effective index Re(n_{eff}) seen by the guided mode as the width W of the stack 103 increases. This course makes it possible to determine an associated index contrast. Δn_{eff} (W_{B}−W_{A}) for two distinct widths W_{A} and W_{B}. Since the coupling force with the lateral gratings 201, 202 depends on the index contrast Δn_{eff}, it is possible, by virtue of this parametric study, to determine depths D201, D202 (for example equal to (W_{B}−W_{A})/2) of the first and second lateral gratings 201, 202. Widths W_{A} and W_{B} correspond to the extreme widths W0 and W1 of the stack 103 in FIG. 2. As an example, considering W_{A}=8 μm and W_{B}=9.5 μm, the sum of the depths enabling a desired coupling force κ=2 Δ_{neff}/λ to be achieved is, for example

$$D 201 + D 202 = {W}_{B} - {W}_{A} = 1.5 µm$$

Each lateral grating 201, 202 can thus have, for the desired coupling force κ, a depth D201, D202 of 0.75 μm.

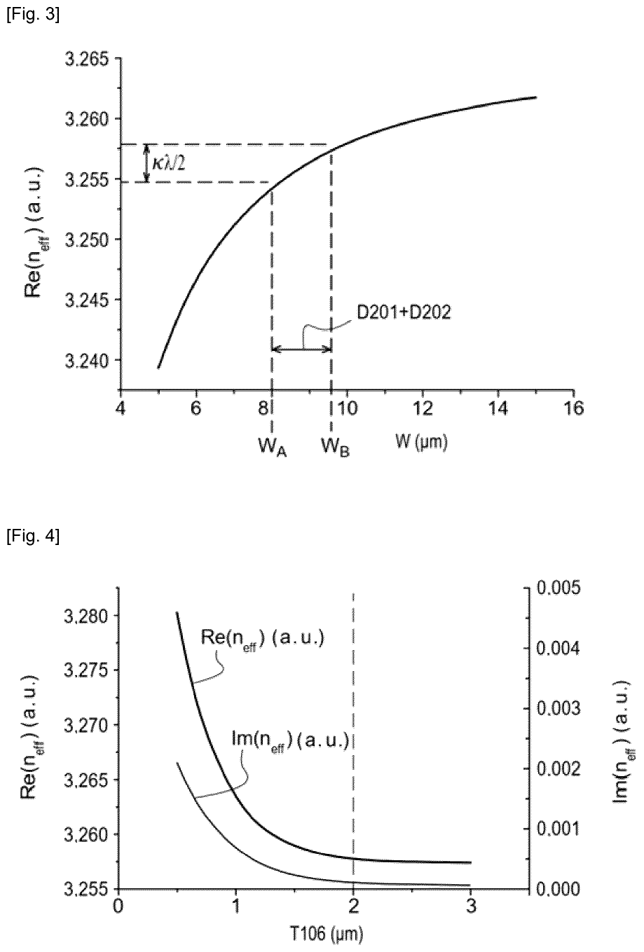

FIGS. 4 and 5 show the results of two parametric studies of the real Re(n_{eff}) and imaginary Im(n_{eff}) parts of the effective index seen by the guided mode in an optical cavity 120 according to the invention. The parametric studies are made as a function of, respectively, the thickness T106 of the upper confinement layer 106 (FIG. 4) and the thickness T105 of the lower confinement layer 105 (FIG. 5).

The imaginary part Im(n_{eff}) accounts for the optical losses of the guided mode in the cavity 120. It corresponds especially to the coupling of the guided mode with the upper metal layer 118 (for FIG. 4) and the lower metal layer 111 (for FIG. 5). The higher the imaginary part Im(n_{eff}) the greater the optical losses.

The optical losses (and therefore the imaginary part Im(n_{eff}) of the effective index) decrease monotonically with the thicknesses T105, T106. It is therefore necessary to increase the thickness T105, T106 of the confinement layers 105, 106 to reduce optical losses. At a low thickness T105, T106, decrease of the losses can be fast. There is, however, a thickness from which losses do not decrease faster than an asymptotic state. When this state is reached, the reduction in optical losses is achieved at the expense of a substantial thickening of the confinement layers. It is therefore wise to identify the thickness T105, T106 from which the asymptotic state is reached. Thus, the selection of a thickness T105, T106 enabling an asymptotic reduction in losses to be achieved provides a good compromise between reduced thickness and acceptable losses.

It should be noted that as the thicknesses T105, T106 of the confinement layers 105, 106 increase, the real part of the effective index also reaches an asymptotic state towards a fixed value of the effective index.

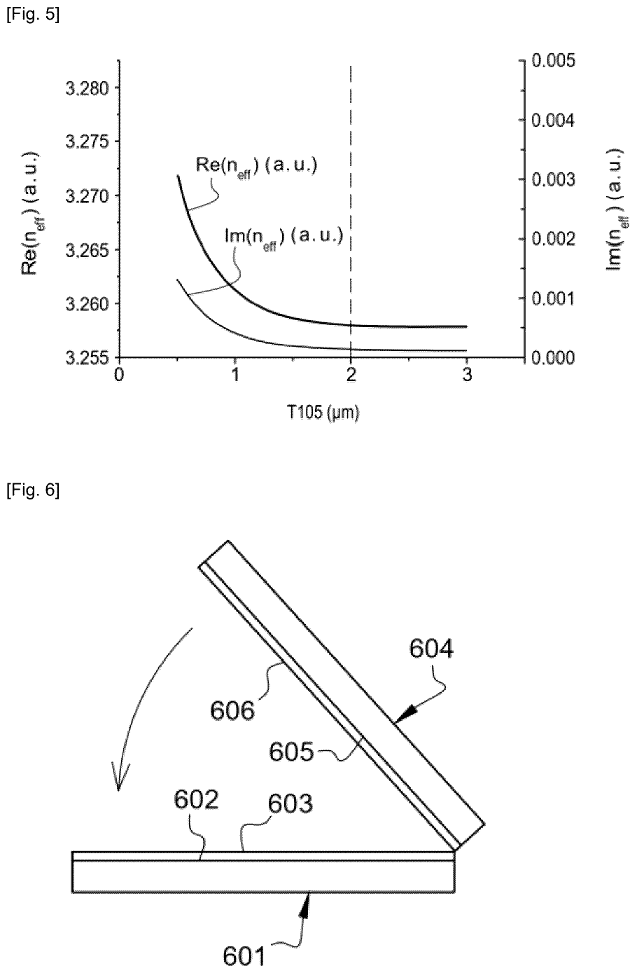

FIG. 6 schematically shows a step of manufacturing a light source 1 according to the invention. Manufacture is carried out from two substrates 601, 604. The first substrate 601 forms the substrate 102 on which the stack 103 of the light source 1 extends. It is of silicon, for example. The first substrate 601 has a first face 602.

The second substrate 604 forms the first confinement layer 105 of the stack 103. It is made of InP, for example. It comprises a second face 605.

In this implementation, the first and second substrates 601, 604 have first and second optical indices n₆₀₁, n₆₀₄ such that n₆₀₁>n₆₀₄. Thus, the first substrate 601 is likely to induce optical losses by transmission of the guided modes.

Manufacturing the source 1 comprises a step of metallising the first and second faces 602, 605 of the first and second substrates 601, 604, forming first and second metal sublayers 603, 606. The transfer of the metallised faces 602, 605 against each other is made so as to bond the second substrate 604 to the first substrate 601.

The two metal sublayers 603, 606 form a first and single metal layer 111 extending between the two substrates 601, 604. This first metal layer 111 is intended to form the lower metal layer 111 of the source 1, separating the stack 103 from the silicon substrate 102.

Manufacturing the source 1 may comprise a subsequent step of forming a stack of layers from the two bonded substrates 601, 604. The formation comprises, for example, etching the second substrate 604 so as to form the lower confinement layer 105 of the stack 103, extending against the lower metal layer 111. Etching is for example carried out through a hard mask, with a stop on the lower metal layer 111. The active region 104 and the upper confinement layer 106 can be deposited onto the lower confinement layer 105. Alternatively, before delimiting the lower confinement layer 105, layers intended to form the active region 104 and the upper confinement layer 106 are deposited onto the second substrate 604. Thus, delimiting the lower confinement layer 105 in the second substrate 604 delimits the active region 104 and the upper confinement layer 106 at the same time.

This delimitation (of the lower and upper confinement layers 105, 106 and of the active region 104) is preferentially carried out so that the final stack 103 comprises at least one corrugation on one of its sides 107, 108. This corrugation makes it possible to form the diffraction grating 201 enabling feedback to be applied to a resonant mode. The corrugation is obtained, for example, through an etching mask with a crenellated edge.

The method advantageously comprises conformally depositing the insulating layers 115, 117 onto the sides of the stack 103 and especially against the lateral corrugation or corrugations. The method also advantageously comprises conformally depositing the lateral metal layers 112, 113 against the insulating layers 115, 117.

The optical indices of the layers forming the stack 103 can be selected so that at least one stationary mode of an electromagnetic field in the stack has an effective optical index n_{eff}. The resulting stack extends over a first metal layer 111, the latter making it possible to limit the propagation of guided modes towards the first substrate 601, even if the latter has a higher optical index than the effective optical index. n_{eff} seen by the guided modes.

The thicknesses T105, T106 of the first and second confinement layers 105, 106 are preferentially determined so that the optical losses associated with at least one of the guided modes of the stack 103 decrease in an asymptotic state. The steps of forming the first and second confinement layers 105, 106 are then carried out so that these layers 105, 106 have the thicknesses determined. These thicknesses T105, T106 are preferably calculated by means of parametric analyses as illustrated by FIGS. 4 and 5.

1. A light source comprising:
a substrate extending in parallel to a plane;
a distributed feedback resonant cavity, configured so that at least one stationary mode of an electromagnetic field, referred to as the resonant guided mode, is established in parallel to the substrate, said resonant cavity comprising a stack of:
a first confinement layer, referred to as the lower confinement layer, extending in parallel to the substrate;
an active layer, configured to generate said electromagnetic field, said active layer extending over the lower confinement layer;
a second confinement layer, referred to as the upper confinement layer, extending over the active layer,
wherein the substrate has an optical index higher than the effective index seen by the resonant guided modes in the resonant cavity and in that the resonant cavity comprises a metal layer, referred to as the lower metal layer, configured to prohibit transmission of the resonant guided modes, the lower metal layer extending in parallel to the substrate, between the substrate and the stack of layers, and wherein the lower confinement layer extends against the lower metal layer.

2. The source according to claim 1, wherein the stack of layers has a height, measured perpendicularly to the substrate, the stack of layers further comprising a first side, extending perpendicularly to the substrate over at least part of the height of the stack of layers and extending in parallel to a first direction parallel to the substrate, referred to as the direction of propagation, the stack of layers having, on its first side, a first diffraction grating configured to apply distributed feedback to said at least one resonant guided mode.

3. The source according to claim 1, wherein the stack of layers has a width, measured perpendicularly to the direction of propagation, the first diffraction grating being formed so that the width of the stack of layers varies periodically as a function of a position along the direction of propagation.

4. The source according to claim 1, wherein the first diffraction grating has a first length, measured along the direction of propagation, and, for at least one resonant guided mode of the resonant cavity, a first coupling force with said resonant guided mode, the product of the first coupling force for said at least one resonant guided mode and the first length of the diffraction grating being between 1 and 2.5.

5. The source according to claim 1, wherein the stack of layers comprises a second side, opposite to the first side, and extending over at least part of the height of the stack of layers, the stack of layers having, on its second side, a second diffraction grating configured to apply distributed feedback to said at least one resonant guided mode, the first diffraction grating having a first pitch and the second diffraction grating having a second pitch equal to the first pitch.

6. The source according to claim 1, wherein the stack of layers has a first face, referred to as the lower face, and a second face, referred to as the upper face, opposite to the lower face, the lower metal layer extending against the lower face of the stack of layers, the stack of layers having, on its upper face, a third diffraction grating configured to apply distributed feedback to said at least one resonant guided mode, the first diffraction grating having a first pitch and the third diffraction grating having a third pitch equal to the first pitch.

7. The source according to claim 1, wherein the lower confinement layer has a first thickness, measured perpendicularly to the substrate, for which optical losses of at least one resonant guided mode of the stack are a function of the first thickness in an asymptotic state.

8. The source according to claim 1, wherein the stack of layers has a lower face and an upper face opposite to the lower face, the lower metal layer extending against the lower face, the resonant cavity also comprising an additional metal layer, referred to as the upper metal layer, extending against the upper face of the stack, the upper confinement layer having a second thickness, measured perpendicularly to the substrate, for which optical losses of at least one resonant guided mode of the stack are a function of the second thickness in an asymptotic state.

9. The source according to claim 1, wherein the lower metal layer is made from Au, Ag or Ti.

10. A method for manufacturing a light source comprising:
providing a first substrate having a first face;
providing a second substrate having a second face;
metallising the first face of the first substrate so as to form a first metal sublayer extending over the first face of the first substrate;
metallising the second face of the second substrate so as to form a second metal sublayer extending over the second face of the second substrate;
transferring the second metal sublayer of the second substrate onto the first metal sublayer of the first substrate so that the first and second metal sublayers form a metal layer, referred to as the lower metal layer, extending in parallel to the first substrate;
forming a distributed feedback resonant cavity configured so that at least one stationary mode of an electromagnetic field, referred to as a resonant guided mode, is established in parallel to the first substrate, forming the resonant cavity comprising the steps of:
etching the second substrate so as to form a first confinement layer, referred to as the lower confinement layer, extending in parallel to the first substrate and against the lower metal layer;
forming an active layer configured to generate said electromagnetic field, said active layer extending over the lower confinement layer; and
forming a second confinement layer, referred to as the upper confinement layer, extending over the active layer,
the substrate having a higher optical index than the effective index seen by the resonant guided modes in the resonant cavity and the lower metal layer being configured to prohibit transmission of the resonant guided modes.

11. The manufacturing method according to claim 10, comprising determining a first thickness for the lower confinement layer, for which optical losses of at least one resonant guided mode of the resonant cavity are a function of this first thickness in an asymptotic state, the etching of the second substrate being carried out so that the resulting lower confinement layer has the first thickness determined.

12. The manufacturing method according to claim 1, comprising determining a second thickness for the upper confinement layer, for which optical losses of at least one resonant guided mode of the resonant cavity are a function of this second thickness in an asymptotic state, the forming of the upper confinement layer being carried out so that the resulting upper confinement layer has the determined second thickness.

13. The manufacturing method according to claim 1, comprising etching the stack of layers so that said stack of layers, having a height measured perpendicularly to the first substrate, comprises a first side, extending perpendicularly to the first substrate over at least part of the height of the stack of layers and extending in parallel to a first direction parallel to the first substrate, referred to as the direction of propagation, etching the stack of layers being carried out so that the stack of layers has, on its first side, a first diffraction grating configured to apply a distributed feedback to said at least one resonant guided mode.

14. The manufacturing method according to claim 13, comprising conformally depositing a first insulating layer against the first side of the stack of layers and a step of conformally depositing an additional metal layer onto the first insulating layer.
